(19) United States
(12) Patent Application Publication
(10) Pub. No.: US 2016/0071957 A1
(43) Pub. Date: Mar. 10, 2016

(54) METHOD FOR MANUFACTURING SEMICONDUCTOR DEVICE

(71) Applicant: KABUSHIKI KAISHA TOSHIBA, Tokyo (JP)

(72) Inventors: Yusuke OSHIKI, Kuwana (JP); Mitsuhiro OMURA, Kuwana (JP)

(21) Appl. No.: 14/643,591

(22) Filed: Mar. 10, 2015

(30) Foreign Application Priority Data
Sep. 5, 2014 (JP) 2014-181731

(51) Int. Cl. H01L 29/66; H01L 21/3065; H01L 27/115; H01L 21/306; H01L 21/311; H01L 21/308; H01L 21/31; H01L 21/283

(52) U.S. Cl. CPC H01L 29/66833; H01L 21/31; H01L 21/3065; H01L 21/283; H01L 21/30604; H01L 21/31111; H01L 21/3081; H01L 27/11582

(57) ABSTRACT

According to one embodiment, a method for manufacturing a semiconductor device includes forming a mask layer above an etching object layer, the mask layer having a plurality of first layers, a plurality of spaces each provided between the first layers, and an opening part penetrating the first layers and communicating with the spaces; and dry etching the etching object layer of a different kind of material from a kind of material of the first layers using the mask layer.

### CROSS-REFERENCE TO RELATED APPLICATION

This application is based upon and claims the benefit of priority from Japanese Patent Application No. 2014-181731, filed on Sep. 5, 2014; the entire contents of which are incorporated herein by reference.

### FIELD

Embodiments described herein relate generally to a method for manufacturing a semiconductor device.

### BACKGROUND

A memory device having a three-dimensional structure is proposed. In the memory device having the three-dimensional structure, a memory hole is formed in a stacked body having a plurality of electrode layers functioning as control gates in memory cells stacked via insulating layers, and a silicon body as a channel is provided on the side wall of the memory hole via a charge storage film.

When a layer forming the memory hole is thicker with increase of bit density, formation of the memory hole having a higher aspect ratio is required. In etching of the memory hole having the higher aspect ratio, control of shape and dimensions is harder.

### BRIEF OF THE DRAWINGS

FIG. 1 is a schematic perspective view of a semiconductor device of an embodiment;

FIG. 2 is an enlarged schematic sectional view of a part of the semiconductor device of the embodiment;

FIGS. 3A to 5 are schematic sectional views showing a method for manufacturing the semiconductor device of the embodiment;

FIG. 6 is a chart showing a relationship between a collision distance Y of a recoil ion and a recoil angle θ2;

FIG. 7 is a schematic sectional view showing a method for manufacturing the semiconductor device of the embodiment; and

FIG. 8 is a schematic sectional view showing an example of a deterioration of a hole form.

### DETAILED DESCRIPTION

According to one embodiment, a method for manufacturing a semiconductor device includes forming a mask layer above an etching object layer, the mask layer having a plurality of first layers, a plurality of spaces each provided between the first layers, and an opening part penetrating the first layers and communicating with the spaces; and dry etching the etching object layer of a different kind of material from a kind of material of the first layers using the mask layer.

Embodiments will now be described with reference to the drawings. In the respective drawings, like members are labeled with like reference numerals.

In the embodiments, a semiconductor memory device having a memory cell array with a three-dimensional structure will be described as a semiconductor device.

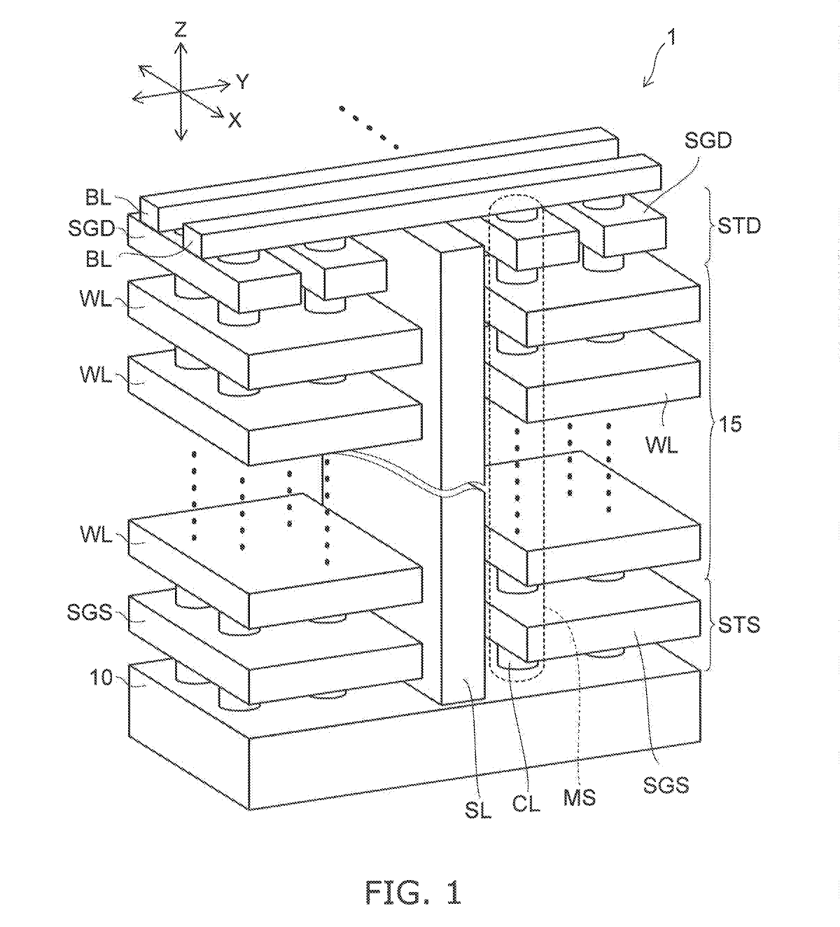

FIG. 1 is a schematic perspective view of a memory cell array 1 of an embodiment. In FIG. 1, insulating layers are not shown for visibility.

In FIG. 1, two directions in parallel to a major surface of a substrate 10 and orthogonal to each other are an X-direction (first direction) and a Y-direction (second direction), and a direction orthogonal to both the X-direction and the Y-direction is a Z-direction (third direction, stacking direction).

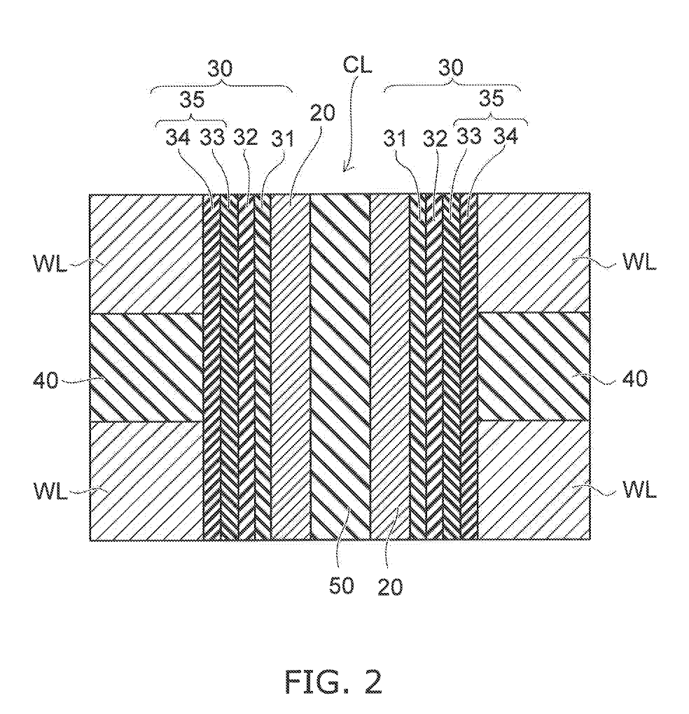

On the substrate 10, source side select gates (lower gate layers) SGS are provided via an insulating layer. On the source side select gates SGS, a stacked body 15 in which a plurality of electrode layers WL and a plurality of insulating layers 40 (FIG. 2) are alternately stacked one by one is provided. On the uppermost electrode layer WL, drain side select gates (upper gate layers) SGD are provided via an insulating layer.

The source side select gates SGS, the drain side select gates SGD, and the electrode layers WL are e.g. silicon layers containing silicon as a major component and e.g., boron is doped in the silicon layers as an impurity for providing conductivity. Or, the source side select gates SGS, the drain side select gates SGD, and the electrode layers WL may contain metal silicide. Or, the source side select gates SGS, the drain side select gates SGD, and the electrode layers WL are metal layers (e.g., layers mainly containing tungsten).

On the drain side select gates SGD, a plurality of bit lines BL (metal films) are provided via an insulating layer (not shown). The drain side select gates SGD extend in the X-direction and the bit lines LB extend in the Y-direction.

A plurality of columnar portions CL penetrate the stacked body 15. The columnar portions CL extend in the stacking direction of the stacked body 15 (Z-direction). The columnar portions CL are formed in e.g. circular cylinder shapes or elliptic cylinder shapes.

The stacked body 15, the source side select gates SGS, the drain side select gates SGD are separated into pluralities of parts in the Y-direction. In the separation part, e.g., a source layer SL is provided.

The source layer SL contains e.g. metal. The lower end of the source layer SL is connected to the substrate 10. The upper end of the source layer SL is connected to upper layer wiring (not shown). Insulating films (not shown) are provided between the source layer SL and the electrode layers WL, the source layer SL and the source side select gates SGS, and the source layer SL and the drain side select gates SGD.

FIG. 2 is an enlarged schematic sectional view of a part of the columnar portion CL.

The columnar portion CL is formed within a memory hole 91 (shown in FIG. 4B) formed in the stacked body 15. Within the memory hole 91, a channel body 20 as a semiconductor channel is provided. The channel body 20 is e.g. a silicon film consisting primarily of silicon. The channel body 20 substantially contains no impurity.

The channel body 20 is formed in a tubular shape extending in the stacking direction of the stacked body 15. The upper end part of the channel body 20 penetrates the drain side select gate SGD and is connected to the bit lines BL shown in FIG. 1.

The lower end part of the channel body 20 penetrates the source side select gate SGS and is connected to the substrate 10. The lower end of the channel body 20 is electrically connected to the source layer SL via the substrate 10.

As shown in FIG. 2, a memory film 30 is provided between the side wall of the memory hole and the channel body 20. The memory film 30 has a block insulating film 35, a charge storage film 32, and a tunnel insulating film 31. The memory film 30 is formed in a tubular shape extending in the stacking direction of the stacked body 15.

Between the electrode layers WL and the channel body 20, the block insulating film 35, the charge storage film 32, and the tunnel insulating film 31 are sequentially provided from the electrode layers WL side. The block insulating film 35 is in contact with the electrode layers WL, the tunnel insulating film 31 is in contact with the channel body 20, and the charge storage film 32 is provided between the block insulating film 35 and the tunnel insulating film 31.

The memory film 30 surrounds the outer circumferential surface of the channel body 20. The electrode layers WL surround the outer circumferential surface of the channel body 20 via the memory film 30. Inside of the channel body 20, a core insulating film 50 is provided.

The electrode layer WL functions as a control gate of the memory cell. The charge storage film 32 functions as a data memory layer that accumulates charge injected from the channel body 20. The memory cell having a vertical transistor structure with the channel surrounded by the control gate is formed in an intersection part between the channel body 20 and each electrode layer WL.

The semiconductor memory device of the embodiment is a nonvolatile semiconductor memory device that may electrically freely erase and write data and hold memory contents after power is turned off.

The memory cell is egg, a charge-trap memory cell. The charge storage film 32 has many trap sites for trapping charge and includes e.g. a silicon nitride film.

The tunnel insulating film 31 serves as a potential barrier when charge is injected from the channel body 20 into the charge storage film 32 or when the charge accumulated in the charge storage film 32 is diffused into the channel body 20. The tunnel insulating film 31 includes e.g. a silicon oxide film. As the tunnel insulating film 31, a stacked film having a structure in which a silicon nitride film is sandwiched by a pair of silicon oxide film (ONO film) may be used. When the ONO film is used as the tunnel insulating film 31, erase operation in the lower electric field can be performed compared to a single layer of the silicon oxide film.

The block insulating film 35 prevents diffusion of the charge accumulated in the charge storage film 32 into the electrode layers WL. The block insulating film 35 has a cap film 34 provided in contact with the electrode layers WL and a block film 33 provided between the cap film 34 and the charge storage film 32.

The block film 33 is e.g. a silicon oxide film. The cap film 34 is a film having higher dielectric constant than the silicon oxide film, e.g. a silicon nitride film, aluminum oxide film, hafnium oxide film, yttrium oxide film, or the like. The cap film 34 is provided in contact with the electrode layers WL, and thereby, back tunnel electrons injected from the electrode layers WL during erasing may be suppressed.

As shown in FIG. 1, a drain side select transistor STD is provided in the upper end part of the columnar portion CL and a source side select transistor STS is provided in the lower end part.

The memory cell, the drain side select transistor STD and the source side select transistor STS are vertical transistors in which currents flow in the stacking direction (Z-direction) of the stacked body 15.

The drain side select gate SGD functions as a gate electrode (control gate) of the drain side select transistor STD. Between the drain side select gate SGS and the channel body 20, an insulating film (not shown) functioning as a gate insulating film of the drain side select transistor STD is provided.

The source side select gate SGS functions as a gate electrode (control gate) of the source side select transistor STS. Between the source side select gate SGS and the channel body 20, an insulating film (not shown) functioning as a gate insulating film of the source side select transistor STS is provided.

Between the drain side select transistor STD and the source side select transistor STS, the plurality of memory cells with the respective electrode layers WL as the control gates are provided. Those plurality of memory cells, the drain side select transistor STD, and the source side select transistor STS are series-connected through the channel body 20 and forms one memory string MS. A plurality of the memory strings MS are arranged in the X-direction and the Y-direction, and thereby, the plurality of memory cells are three-dimensionally provided in the X-direction, the Y-direction, and the Z-direction.

The memory hole in which the columnar portion CL is formed is formed by e.g. Reactive Ion Etching (RIE). To increase the storage capacity, high-density formation of the memory cells is performed. For example, the memory having a hole diameter of not more than 100 nm and about several tens of stacked layers of the electrode layers WL are formed, and the memory hole in this regard is a micro hole having a very high aspect ratio.

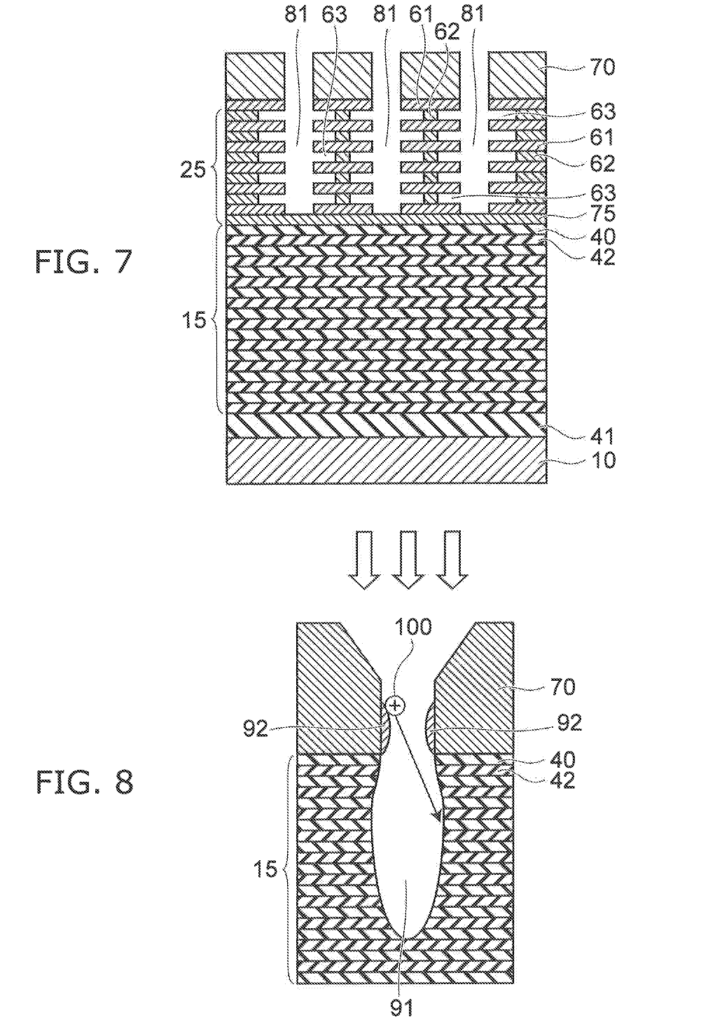

Generally, in the RIE technology, as shown in FIG. 8, with progress of the processing of an etching object layer 15, angular portions (shoulder portions) contiguous to the opening part of a mask layer 70 are likely to be sputtered and scraped by ions into tapered shapes. Further, the sputtered mask material may be deposited on the side surface of the opening part. When an ion 100 recoils from the tapered surface of the shoulder portion of the mask layer 70 or a deposited material 92 on the side surface of the opening part, the ion 100 travels in an oblique direction, not straight downward. By the recoil ion, side etching may progress with respect to the side surface of the hole 91 and the side surface of the hole 91 may be a bowing shape. Or, the opening part may be obstructed by the deposited materials 92 attached to the side surface of the opening part and etching may be stopped halfway. If the storage capacity becomes still larger and the thickness of the etching object layer 15 increases, it is expected that the aspect ratio of the memory hole 91 increases and hole formation in an appropriate shape becomes more and more difficult.

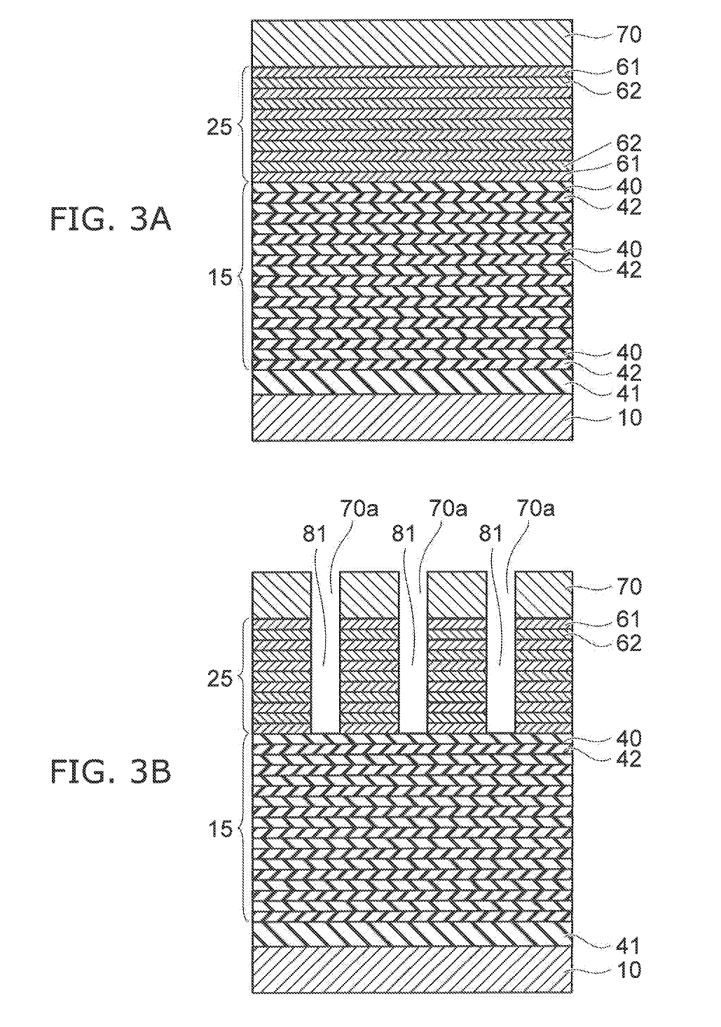

As below, a method for forming the memory hole of the semiconductor memory device of the embodiment will be described with reference to FIGS. 3A to 4B.

As shown in FIG. 3A, the etching object layer (foundation layer) 15 is formed on the substrate 10 via an insulating layer 41. The etching object layer 15 is a stacked body having a plurality of sacrifice layers (third layers) 42 and a plurality of insulating layers (fourth layers) 40. The substrate 10 is e.g. a semiconductor substrate and silicon substrate.

On the insulating layer 41, the sacrifice layers 42 and the insulating layers 40 are alternately formed. A process of alternately forming the sacrifice layers 42 and the insulating layers 40 is repeated at a plurality of times. The insulating layer 40 is provided between the sacrifice layers 42. The sacrifice layers 42 are replaced by the electrode layers WL in the following process.

The insulating layer 41 and the insulating layers 40 are e.g. silicon oxide films (SiO₂ films). The sacrifice layers 42 are films of a different kind of material from those of the insulating layer 41 and the insulating layers 40, e.g. silicon nitride films (SiN films).

On the etching object layer (stacked body) 15, a mask layer 25 is formed. The mask layer 25 is a stacked film having a plurality of first layers 61 and a plurality of second layers 62.

On the etching object layer 15, the first layers 61 and the second layers 62 are alternately formed. A process of alternately forming the first layers 61 and the second layers 62 is repeated at a plurality of times. The second layer 62 is provided between the first layers 61.

The first layers 61 and the second layers 62 are layers of a different kind of material from that of the etching object layer 15. The first layers 61 are e.g. non-doped amorphous silicon layers. The second layers 62 are impurity (e.g. boron)-doped amorphous silicon layers. The first layers 61 are substantially (intentionally) undoped with an impurity. The impurity concentration of the first layers 61 is lower than the impurity concentration of the second layers 62.

On the mask layer (first mask layer) 25, the mask layer (second mask layer) 70 is formed. The mask layer 70 is a layer of a different kind of material from those of the etching object layer 15 and the mask layer 25, e.g. a carbon layer.

The etching object layer 15, the mask layer 25, and the mask layer 70 are formed by e.g. Chemical Vapor Deposition (CVD).

The numbers of stacked layers of the sacrifice layers 42 and the insulating layers 40 and the numbers of stacked layers of the first layers 61 and the second layers 62 are not limited to the numbers of layers shown in the drawings.

In the mask layer 70, a plurality of opening parts (holes) 70a are formed as shown in FIG. 3B by RIE using a resist mask (not shown).

Then, by RIE using the mask layer 70 having the opening parts 70a formed therein, a plurality of opening parts (holes) 81 are formed in the mask layer 25 (stacked film) 25. Using the same etching gas (e.g. a gas containing halogen and oxygen (O₂)), both of the silicon-based first layers 61 and second layers 62 are non-selectively and continuously etched.

When the aspect ratio of the opening part (hole) 81 is relatively low, a mixed gas of HBr, O₂, Cl₂ is used, and, when the aspect ratio is relatively high, a mixed gas of HBr, O₂, CF₄ is used. Further, when the aspect ratio is higher, the gas pressure within the etching chamber is made higher and the bias voltage applied to the wafer side including the etching object layer 15 is made higher than those when the aspect ratio is lower.

F has higher reactivity with Si than Cl, and Cl has higher reactivity with Si than Br. In the hole with the higher aspect ratio, the etching rate may be made higher by adding F to the etching gas, In the hole formation with the lower aspect ratio, side etching is easily caused due to the higher reactivity of F with Si, and it is desired that use of F is suppressed.

The opening parts (holes) 81 penetrate the mask layer 25 and reach the etching object layer 15. The etching object layer 15 is exposed on the bottoms of the opening parts (holes) 81.

After the formation of the opening parts (holes) 81, the second layers 62 are selectively removed with the first layers 61 left as shown in FIG. 4A by chemical processing (wet etching) through the opening parts 81. For the chemical processing, e.g. a choline aqueous solution is used. With respect to the chemical processing, the second layers 62 having higher boron concentration than the first layers 61 are etched.

By the chemical processing, the second layers 62 recede from the opening parts 81 in the width direction of the opening parts 81 (the diameter direction of the holes). That is, parts at the opening parts 81 side in the second layers 62 are removed and spaces 63 communicating with the opening parts 81 are formed. The other parts of the second layers 62 are left between the first layers 61 and support the plurality of first layers 61.

By selective removal of the second layers 62, the mask layer 25 having the plurality of first layers 61 and the plurality of spaces 63 each provided between the first layers 61 is formed. The mask layer 25 has a grating structure in which the first layers 61 and the spaces 63 are alternately arranged (stacked) over the whole region in the thickness direction. The grating structure may be formed over the whole region in the thickness direction of the mask layer 25 or formed only in a partial region in the thickness direction of the mask layer 25.

The thicknesses of the respective first layers 61 are nearly equal. The thicknesses of the respective second layers 62 are nearly equal. Therefore, the heights of the respective spaces 63 are nearly equal. The first layers 61 and the spaces 63 are repeated with equal pitches in the thickness direction of the mask layer 25.

By RIE using the mask layer 25, the etching object layer 15 under the opening part 81 is etched, and, as shown in FIG. 4B, the memory hole 91 is formed in the etching object layer 15 under the opening part 81. Using the same etching gas (e.g. a gas containing fluorocarbon or hydrofluorocarbon), the sacrifice layers and the insulating layers 40 are non-selectively and continuously etched.

As shown in FIG. 4A, etching of the etching object layer 15 is progressed with the mask layer 70 left on the mask layer 25 having the grating structure. With the progress of the etching, the mask layer 70 disappears as shown in FIG. 4B.

The first layers 61 of the mask layer 25 are formed of a different material from those of the insulating layers 40 and the sacrifice layers 42 of the etching object layer 15, and have sufficient etching resistance as an etching mask to RIE of the etching object layer 15. Note that the difference in material here includes a difference between non-doped silicon and doped silicon.

Depending on the combination of the material of the etching object layer 15 and the material of the mask layer 25 and the etching condition, the first layers 61 are also consumed at the RIE, however, the etching rate of the first layers 61 is sufficiently lower than the etching rate of the etching object layer 15.

The material, the number of layers, the thickness, the etching condition (the kind of gas), etc. of the first layer 61 are set so that the etching of the etching object layer 15 may be ended before the first layers 61 completely disappear. Further, in order to sufficiently fulfill the function by the spaces 63, which will be described later, it is desired to set the number of layers, the thickness, etc. of the first layer 61 so that at least the spaces 63 for about several layers may be held even if the first layers 61 disappear during etching of the etching object layer 15.

FIG. 4B shows an enlarged section near arbitrary one opening part 81.

The mask layer 25 having the grating structure is used, and thereby, most of the sputtered material of the mask layer 70 and material of the first layers 61 may enter the spaces 63 and may be deposited in the spaces 63. Therefore, the opening part 81 of the mask layer 25 is harder to be obstructed by the deposit materials 92.

Further, the ion 100 recoiling from the tapered surface formed by recession of the angular portion (shoulder portion) of the mask layer 70 or the first layer 61 can enter the space 63, and side etching of the mask layer 25 and the etching object layer 15 by the recoil ion 100 is suppressed.

Furthermore, the deposit materials 92 are deposited in the spaces 63 and the deposited materials 92 are harder to be formed to protrude into the opening part 81. Accordingly, the recoil of the ion 100 by the deposited material 92 within the opening part 81 may be suppressed.

Therefore, according to the embodiment, obstruction of the opening parts 81 and the side etching of the memory holes 91 may be suppressed and etching may be progressed in the nearly perpendicular direction to the major surface of the substrate 10. As a result, the memory holes 91 having the straight-shaped side walls with suppressed diameter variations in the depth direction may be easily formed. The memory holes 91 having the proper shapes may suppress e.g. variations in memory cell properties in the stacking direction.

FIG. 5 is a schematic sectional view of a part of the mask layer 25 further enlarged from FIG. 4B.

As shown in FIG. 5, in an arbitrary section in parallel to the depth direction of the opening part (hole) 81, θ2 shows a recoil angle of the ion 100 recoiling from the inner circumferential surface of the first layer 61 forming the side surface of the opening part (hole) 81, and θ1 shows an incident angle of the recoiling ion 100 to the side surface of the opening part 81 at the opposite side with the center axis of the opening part (hole) 81 in between.

Y shows a distance in the depth direction at which the recoiling ion 100 next reaches (collides with) the side surface of the opening part 81. W shows a width of the space 63 between one end at the opening part 81 side and the other end at the far side from the opening part 81 (an amount of recession of the second layer 62 from the opening part 81). T shows a thickness of the first layer 61. X shows a dimension in the width direction (the hole diameter) of the opening part 81. P shows a repetition pitch of the first layer 61 and the space 63.

There is a tendency that, when the ion 100 enters the inner circumferential surface of the first layer 61 at the incident angle θ1 of 45°, the rate of etching the first layer 61 becomes the highest.

If the thickness T of the first layer 61 is larger than the dimension X in the width direction (the hole diameter) of the opening part 81, there is a possibility that the recoil ion 100 enters the inner circumferential surface of the first layer 61 at the incident angle of 45°.

If the thickness T of the first layer 61 is smaller than the dimension X in the width direction (the hole diameter) of the opening part 81, the recoil ion 100 having the incident angle 81 of 45° enters the space 63. Therefore, in order to suppress the side etching of the first layer 61 by the recoil ion 100, it is desired to make the thickness T of the first layer 61 smaller than the dimension X in the width direction of the opening part 81.

Further, in order to sufficiently absorb the deposited material in the space 63, it is desired to make the width W of the space 63 larger than the dimension X in the width direction of the opening part 81.

There is a tendency that, as the distance (collision distance) Y in the depth direction at which the recoil ion 100 next reaches (collides with) the side surface of the opening part 81 is smaller, the ion 100 collides with the side surface of the opening part 81 with larger energy. According to the experiments of the inventors, in RIE for forming a hole having a diameter of several tens of nanometers, when the collision distance of the recoil ion 100 is not more than 180 nm, the bowing shape of the hole side surface due to side etching prominently appeared.

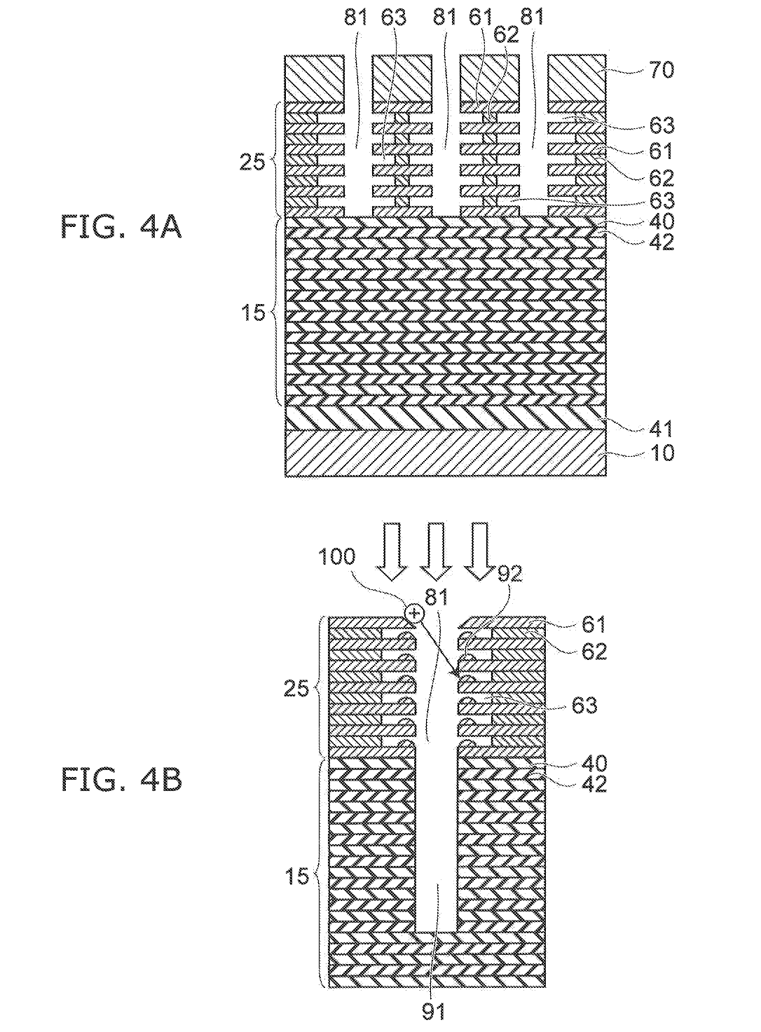

FIG. 6 shows results of calculation of relationships between the collision distance Y of the recoil ion 100 and the recoil angle θ2. The solid line, broken line, and dashed-dotted line show characteristics when the dimension X in the width direction (the hole diameter) of the opening part 81 is 40 n 50 nm, and 60 nm, respectively.

From the results in FIG. 6, it is known that, if the recoil angle θ2 is larger than 15°, the collision distance Y of the recoil ion is smaller than 180 nm.

It is considered that, if the recoil angle θ2 is not larger than 15°, the collision distance Y of the recoil ion 100 is larger than 180 nm and the bowing shape of the hole side surface is harder to be caused.

As shown in FIG. 5, X/tan θ2 shows the collision distance Y of the recoil ion 100 when the recoil angle is 02. For example, X/tan 15° shows the collision distance Y of the recoil ion 100 when the recoil angle θ2 is 15°.

In view of the fact that the bowing shape of the hole side surface is easier to be caused when the recoil angle θ2 is not smaller than 15°, it is considered that the bowing shape due to recession of the inner circumferential surface of the first layer 61 may be suppressed by allowing the recoil ion 100 to enter the space 63 when the recoil angle 82 is not smaller than 15°. FIG. 5 illustrates the recoil of the ion 100 in the uppermost first layer 61, and the same applies to the recoil of the ion 100 in the other first layers 61 than the uppermost layer.

That is, when the pitch P of the first layer 61 and the space 63 is larger than X/tan 15°, the recoil ion 100 at the recoil angle θ2 not smaller than 15° easily enters the space 63. Therefore, it is desired to set P and X to satisfy P>X/tan 15°.

The memory hole 91 is formed in the etching object layer 15 using the above described mask layer 25 having the grating structure, and then, the sacrifice layers 42 of the etching object layer 15 are removed by etching through the memory hole 9L Then, metal layers (e.g. tungsten layers) are formed as the electrode layers WL in the spaces formed by removal of the sacrifice layers 42.

The electrode layers WL are formed, and then, the memory film 30, the channel body 20, and the core insulating film 50 shown in FIG. 2 are formed on the side wall of the memory hole 91.

Note that the above described embodiment may be applied not only to the hole formation but also to slit formation. That is, in the mask layer 25, slits are formed as the opening parts 81 and slits are formed in the etching object layer 15 by RIE using the mask layer 25. In the slits formed in the etching object layer 15, e.g. source layers SL shown in FIG. 1 are buried via insulating films.

Further, in this case, the memory hole 91 may be first formed, the columnar portion CL may be formed in the hole, and then, the slit may be formed. Then, the sacrifice layers 42 are removed by etching through the slit, and the electrode layers WL are formed. Then, the source layer SL may be formed within the slit.

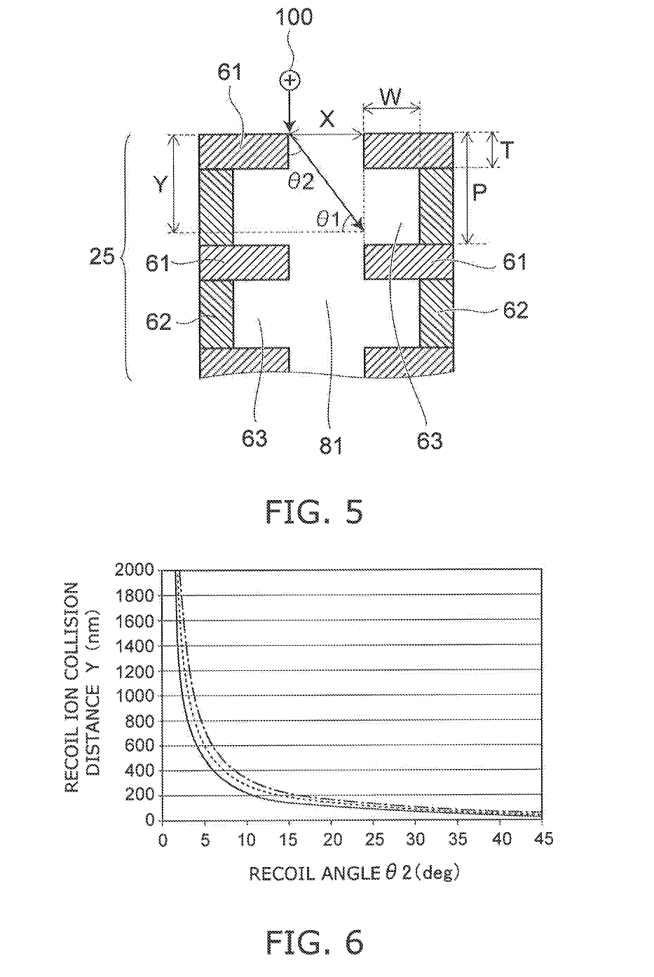

FIG. 7 is a schematic sectional view corresponding to FIG. 4A in the above described embodiment.

In FIG. 7, an intermediate film 75 is formed between the etching object layer 15 and the mask layer 25. The intermediate film 75 is a film of a different kind of material from those of the first layers 61 and the second layers 62 of the mask layer 25. The intermediate film 75 has resistance to etching when the second layers 62 are receded and the spaces 63 are formed. That is, the intermediate film 75 protects the etching object layer 15 at etching of the second layers 62.

In the etching of the second layers 62, the insulating layers 40 and the sacrifice layers 42 of the etching object layer 15 are protected by the intermediate film 75, and the same material as those of the insulating layers 40 and the sacrifice layers 42 may be used for the second layers 62. RIE for processing the etching object layer 15 is anisotropic etching, and the etching of the second layers 62 in the receded positions from the opening part 81 is suppressed.

A combination of the material of the etching object layer 15, the material of the first layers 61, and the material of the second layers 62 of the mask layer 25 is not limited to the above described example. Further, depending on the combination of the materials, e.g. the processing method for receding the second layers 62 varies.

For example, the etching object layer 15 may be formed by alternately and repeatedly stacking metal layers as the third layers in place of the sacrifice layers 42 and silicon oxide layers as insulating layers (fourth layers) 40. In this case, the metal layers serve as the electrode layers WL as they are.

With respect to the etching object layer 15 of the materials, non-doped silicon layers may be used for the first layers 61 of the mask layer 25 and boron-doped silicon layers may be used for the second layers 62. Or, carbon layers formed by CVD may be used for the first layers 61 and organic layers (carbon layers) formed by coating may be used for the second layers 62. Cr, carbon layers formed by CVD may be used for the first layers 61 and non-doped silicon layers may be used for the second layers 62.

Further, the etching object layer 15 may be formed by alternately and repeatedly stacking boron-doped silicon layers as the third layers and silicon oxide layers as insulating layers (fourth layers) 40. In this case, the boron-doped silicon layers serve as the electrode layers WL as they are.

With respect to the etching object layer 15 of the materials, carbon layers formed by CVD may be used for the first layers 61 of the mask layer 25 and organic layers (carbon layers) formed by coating may be used for the second layers 62. Or, carbon layers formed by CVD may be used for the first layers 61 and non-doped silicon layers may be used for the second layers 62. Or, metal layers may be used for the first layers 61 and carbon layers formed by CVD may be used for the second layers 62. Or, carbon layers formed by CVD may be used for the first layers 61 and metal layers may be used for the second layers 62.

Furthermore, silicon nitride layers as the sacrifice layers (third layers) 42 and silicon oxide layers as the insulating layers (fourth layers) 40 are alternately and repeatedly stacked, and, with respect to the etching object layer 15 illustrated in the embodiment, carbon layers formed by CVD may be used for the first layers 61 and organic layers (carbon layers) formed by coating may be used for the second layers 62. Or, carbon layers formed by CVD may be used for the first layers 61 and non-doped silicon layers may be used for the second layers 62. Or, metal layers may be used for the first layers 61 and carbon layers formed by CVD may be used for the second layers 62. Or, carbon layers formed by CVD may be used for the first layers 61 and metal layers may be used for the second layers 62.

In addition, the etching object layer 15 is not limited to the stacked film in which different kinds of films are alternately and repeatedly stacked, but may be a stacked film without any repeated structure or the same kind of single-layer films. The above described embodiments may be applied to formation of holes or slits having higher aspect ratios regardless of the materials and the structure of the etching object layer 15.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A method for manufacturing a semiconductor device comprising:
forming a mask layer above an etching object layer, the mask layer having a plurality of first layers, a plurality of spaces each provided between the first layers, and an opening part penetrating the first layers and communicating with the spaces; and
dry etching the etching object layer of a different kind of material from a kind of material of the first layers using the mask layer.

2. The method according to claim 1, wherein the forming the mask layer includes:
forming a stacked film above the etching object layer, the stacked film having the plurality of first layers and a plurality of second layers each provided between the first layers;
forming the opening part in the stacked film; and
forming the spaces by removing parts of the second layers by etching through the opening part.

3. The method according to claim 2, wherein the forming the mask layer includes:
forming a first mask layer including the stacked film; and
forming a second mask layer on the first mask layer, the second mask layer having a different kind of material from a kind of material of the etching object layer and a kind of material of the first mask layer.

4. The method according to claim 3, wherein the first layers and the second layers are silicon layers and impurity concentration of the first layers is lower than impurity concentration of the second layers, and
the second mask layer is a carbon layer.

5. The method according to claim 2, wherein the first layers and the second layers are silicon layers and impurity concentration of the first layers is lower than impurity concentration of the second layers.

6. The method according to claim 5, wherein boron concentration of the first layers is lower than boron concentration of the second layers.

7. The method according to claim 6, wherein the parts of the second layers are removed by etching using a choline aqueous solution.

8. The method according to claim 5, wherein the etching object layer including silicon nitride layers and silicon oxide layers is etched by Reactive Ion Etching (RIE) using a gas containing fluorocarbon or hydrofluorocarbon.

9. The method according to claim 1, further comprising forming an intermediate film between the etching object layer and the mask layer, the intermediate film having a different kind of material from a kind of material of the first layers and a kind of material of the second layers.

10. The method according to claim 1, wherein the plurality of first layers and the plurality of spaces are repeated with equal pitches in a thickness direction of the mask layer.

11. The method according to claim 1, wherein a thickness of the first layers is smaller than a dimension in a width direction of the opening part.

12. The method according to claim 1, wherein a width of the spaces between one end at the opening part side and another end at a far side from the opening part is larger than a dimension in a width direction of the opening part.

13. A method for manufacturing a semiconductor device comprising:
forming a mask layer above a stacked body, the mask layer having a plurality of first layers, a plurality of spaces each provided between the first layers, and an opening part penetrating the first layers and communicating with the spaces, the stacked body having a plurality of third layers and a plurality of fourth layers each provided between the third layers; and
dry etching the stacked body of a different kind of material from a kind of material of the first layers using the mask layer.

14. The method according to claim wherein the forming the mask layer includes:
forming a stacked film above the stacked body, the stacked film having the plurality of first layers and a plurality of second layers each provided between the first layers;
forming the opening part in the stacked film; and
forming the spaces by removing parts of the second layers by etching through the opening part.

15. The method according to claim 14, wherein the third layers are silicon nitride layers and the fourth layers are silicon oxide layers, and
the first layers and the second layers are silicon layers, and impurity concentration of the first layers is lower than impurity concentration of the second layers.

16. The method according to claim 14, wherein the third layers are silicon nitride layers and the fourth layers are silicon oxide layers, and
the first layers are carbon layers and the second layers are organic layers.

17. The method according to claim 14, wherein the third layers are silicon nitride layers and the fourth layers are silicon oxide layers, and
the first layers are carbon layers and the second layers are silicon layers.

18. The method according to claim 14, wherein the third layers are metal layers and the fourth layers are silicon oxide layers, and
the first layers and the second layers are silicon layers, and impurity concentration of the first layers is lower than impurity concentration of the second layers.

19. The method according to claim 14, wherein the third layers are metal layers and the fourth layers are silicon oxide layers, and
the first layers are carbon layers and the second layers are organic layers.

20. The method according to claim 14, wherein the third layers are metal layers and the fourth layers are silicon oxide layers, and
the first layers are carbon layers and the second layers are silicon layers.
